(19) United States
(12) Patent Application Publication
(10) Pub. No.: US 2013/0043897 A1
(43) Pub. Date: Feb. 21, 2013

(54) TESTING STACKED DIE

(71) Applicants: Rajamani Sethuram, San Diego, CA (US); Karim Arabi, San Diego, CA (US); Sarath Chandra Kasarla, San Diego, CA (US)

(72) Inventors: Rajamani Sethuram, San Diego, CA (US); Karim Arabi, San Diego, CA (US); Sarath Chandra Kasarla, San Diego, CA (US)

(73) Assignee: QUALCOMM INCORPORATED, San Diego, CA (US)

(21) Appl. No.: 13/361,772

(22) Filed: Jan. 30, 2012

Related U.S. Application Data
(60) Provisional application No. 61/525,061, filed on Aug. 18, 2011.

(51) Int. Cl. G01R 31/26; H01L 23/58

(52) U.S. Cl. 324/762.03; 257/48; 257/E23.002

(57) ABSTRACT

An integrated circuit configured for at-speed testing is described. The integrated circuit includes a first die. The first die includes a transition launch point. The integrated circuit also includes a second die. The second die includes a first observe point. The integrated circuit further includes a first through silicon via. The first through silicon via couples the first die to the second die.

### CLAIM OF PRIORITY UNDER 35 U.S.C. §119

The present Application for Patent claims priority to Provisional Application No. 61/525,061 entitled “TESTING STACKED DIE” filed Aug. 18, 2011, and assigned to the assignee hereof and hereby expressly incorporated by reference herein.

### TECHNICAL FIELD

The present disclosure relates generally to wireless communication systems. More specifically, the present disclosure relates to systems and methods for testing stacked die.

### BACKGROUND

Electronic devices (cellular telephones, wireless modems, computers, digital music players, Global Positioning System units, Personal Digital Assistants, gaming devices, etc.) have become a part of everyday life. Small computing devices are now placed in everything from automobiles to housing locks. The complexity of electronic devices has increased dramatically in the last few years. For example, many electronic devices have one or more processors that help control the device, as well as a number of digital circuits to support the processor and other parts of the device.

This increased complexity has led to an increased need for testing that can test digital circuits and/or digital systems. Testing may be used to verify or test various parts of devices, such as pieces of hardware, software or a combination of both. In many cases the equipment used to test a device is a separate piece of equipment than the device being tested.

Integrated circuit real estate can become very expensive. One way to increase the amount of integrated circuit real estate available is to stack two or more dies to form a single integrated circuit. The dies may be coupled together using a Through Silicon Via (TSV). Benefits may be realized by improved systems and methods for testing stacked die.

### SUMMARY

An integrated circuit configured for at-speed testing is described. The integrated circuit includes a first die with a transition launch point. The integrated circuit also includes a second die with a first observe point. The integrated circuit further includes a first through silicon via that couples the first die to the second die.

The second die may be stacked directly on top of the first die. The integrated circuit may also include a third die with a second observe point. The third die may be stacked directly on top of the second die. The integrated circuit may further include a second through silicon via that couples the second die to the third die. Automatic test equipment may apply test signals to the first die using the transition launch point. The automatic test equipment may capture a testing response from the observe point on the second die.

Testing equipment may be coupled to the transition launch point of the first die and the first observe point of the second die. The transition launch point may not impact the timing of a functional path-under-test. The transition launch point may behave as a scan flop during an automatic test pattern generation mode. The transition launch point may include a functional flop, a multiplexer coupled to an input of the functional flop and an inverter.

The functional flop may lead to an output-type through silicon via coupling the first die to the second die. Automatic test equipment may apply test signals to the first die using the transition launch point. The automatic test equipment may capture a testing response from the observe point on the second die. The test signals may include at-speed rising/falling transitions to test for speed-related defects in the first die.

The transition launch point may operate in one of four modes: capture mode, shift mode, through silicon via launch transition mode and through silicon via launch preceding bit mode. The transition launch point may capture data when the transition launch point is in capture mode. When the transition launch point is in shift mode, multiple transition launch points may be daisy chained to form a scan chain. Data may be shifted in/out of the transition launch point. The transition launch point may be operating in through silicon via launch transition mode. Data stored in the transition launch point may then be inverted using an inverter. The transition launch point may be operating in through silicon via launch preceding bit mode. The transition launch point may then launch the data stored in a preceding scan bit.

A method for at-speed testing of an integrated circuit is also described. Transitions are generated to test for speed-related defects in a through silicon via path of the integrated circuit. The transitions are applied to a first die in the integrated circuit using a transition launch point. A response is captured from the integrated circuit using an observe point on a second die. The response is used to determine whether the first die has speed-related defects.

The integrated circuit may include a first through silicon via that couples the first die to the second die. The second die may be stacked directly on top of the first die. The integrated circuit may also include a third die. The third die may include a second observe point. The third die may be stacked directly on top of the first die. The second die may be stacked directly on top of the third die. The integrated circuit may further include a first through silicon via that couples the first die to the third die. The integrated circuit may also include a second through silicon via that couples the second die to the third die.

Automatic test equipment may apply test signals to the first die using the transition launch point. The automatic test equipment may capture a testing response from the observe point on the second die. Testing equipment may be coupled to the transition launch point of the first die and the first observe point of the second die. The transition launch point may not impact the timing of a functional path-under-test. The transition launch point may behave as a scan flop during an automatic test pattern generation mode.

The transition launch point may include a functional flop, a multiplexer coupled to an input of the functional flop and an inverter. The functional flop may lead to an output-type through silicon via coupling the first die to the second die. The method may be performed by automatic test equipment. The transitions may include at-speed rising/falling transitions. The transition launch point may operate in one of four modes: capture mode, shift mode, through silicon via launch transition mode and through silicon via launch preceding bit mode. The transition launch point may capture data when the transition launch point is in capture mode. When the transition launch point is in shift mode, multiple transition launch points may be daisy chained to form a scan chain. Data may be shifted in/out of the transition launch point. The transition launch point may be operating in through silicon via launch transition mode. Data stored in the transition launch point may then be inverted using an inverter. The transition launch point may be operating in through silicon via launch preceding bit mode. The transition launch point may launch the data stored in a preceding scan bit.

An integrated circuit configured for leakage testing is described. The integrated circuit includes a group of through silicon vias that includes a plurality of through silicon vias. The integrated circuit also includes a pass-transistor coupling that couples the group of through silicon vias to testing equipment. The integrated circuit further includes a testing control chain.

The pass-transistor coupling may couple the group of through silicon vias to a port that is accessible by the testing equipment. The pass-transistor coupling may include a first transistor coupled to the group of through silicon vias and a second transistor coupled between the first transistor and the port. The gate of the first transistor may be coupled to a Joint Test Action Group control bit. The gate of the second transistor may be coupled to a test pin. The size of the group of through silicon vias may be based on available Joint Test Action Group control bits or the number of top level pins accessible from the testing equipment.

A method for digital at-speed loop back testing is also described. An internal loop-back structure in a die is created using a pass-transistor coupling. A frequency at which digital at-speed loop back testing should be performed is computed. At-speed loop back testing on the die is performed at the computed frequency.

The die may include an observe point and a transition launch point. The pass-transistor coupling may be coupled between the transition launch point and the observe point. The pass-transistor coupling may include a first transistor coupled to the observe point and a second transistor coupled between the first transistor and the transition launch point. The gate of the first transistor may be coupled to a Joint Test Action Group control bit. The gate of the second transistor may be coupled to a test pin. The first transistor may be coupled to an input through silicon via. The second transistor may be coupled to an output through silicon via. The transition launch point may include a functional flop, a multiplexer coupled to an input of the functional flop and an inverter.

An apparatus configured for at-speed testing of an integrated circuit is described. The apparatus includes means for generating transitions to test for speed-related defects in a through silicon via path of the integrated circuit. The apparatus also includes means for applying the transitions to a first die in the integrated circuit using a transition launch point. The apparatus further includes means for capturing a response from the integrated circuit using an observe point on a second die. The apparatus also includes means for using the response to determine whether the first die has speed-related defects.

A computer-program product for at-speed testing of an integrated circuit is also described. The computer-program product includes a non-transitory computer-readable medium having instructions thereon. The instructions include code for causing an apparatus to generate transitions to test for speed-related defects in a through silicon via path of the integrated circuit. The instructions also include code for causing the apparatus to apply the transitions to a first die in the integrated circuit using a transition launch point. The instructions further include code for causing the apparatus to capture a response from the integrated circuit using an observe point on a second die. The instructions also include code for causing the apparatus to use the response to determine whether the first die has speed-related defects.

### BRIEF DESCRIPTION OF THE DRAWINGS

FIG. 1 shows a system for testing stacked die at the wafer level and/or the package level;

FIG. 2 illustrates stacked dies at the wafer level;

FIG. 3 is a block diagram illustrating an electronic components package that is configured for at-speed testing;

FIG. 4 is a flow diagram of a method for at-speed testing of stacked die;

FIG. 5 is a block diagram illustrating testing using a Joint Test Action Group (JTAG) Test Access Port (TAP) controller;

FIG. 6 is a block diagram illustrating a layout aware leakage test connection;

FIG. 7 is a circuit diagram illustrating a pass-transistor coupling;

FIG. 8 is a flow diagram of a method for performing a leakage test on a die;

FIG. 9 is a circuit diagram illustrating a configuration for digital at-speed loop back testing of a die;

FIG. 10 is a flow diagram of a method for conducting digital at-speed loop back testing; and

FIG. 11 illustrates certain components that may be included within an electronic device/wireless device.

### DETAILED DESCRIPTION

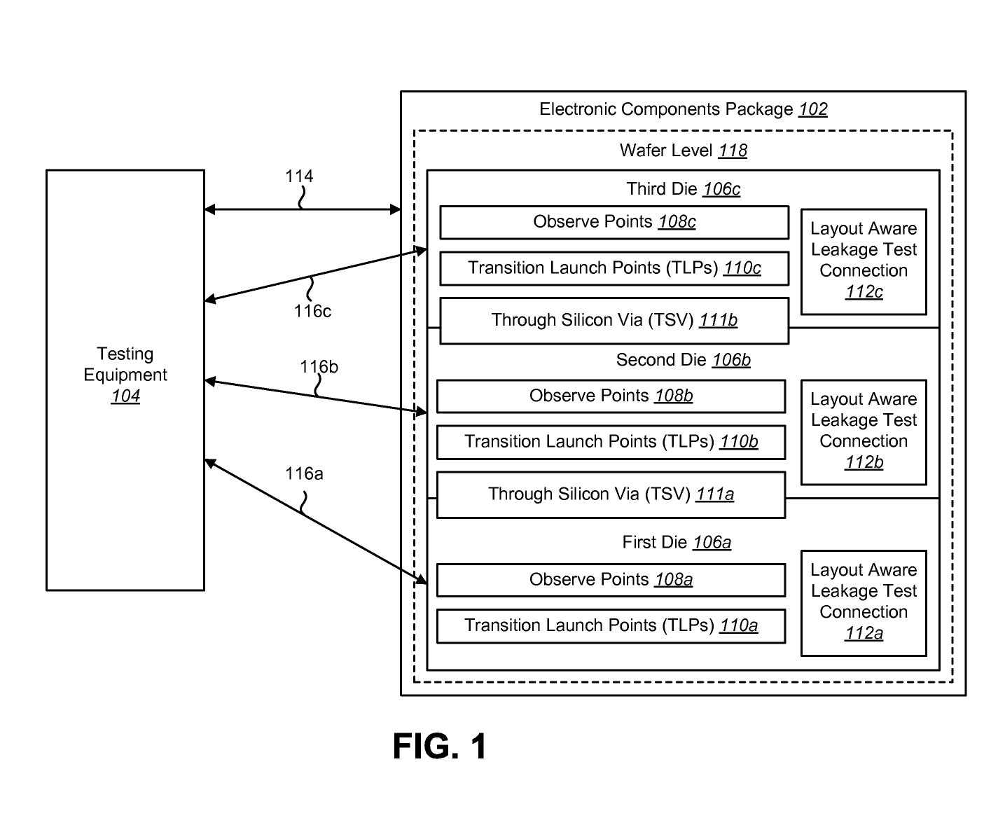

FIG. 1 shows a system for testing stacked die 106 a-c at the wafer level 118 and/or the package level. Testing equipment 104 may be coupled 114 to an electronic component package 102 to test the die 106 at the package level. The testing equipment 104 may also be coupled 116a-c to each stacked die 106a-c to allow testing of each die 106a-c at the wafer level 118. The testing equipment 104 may be automatic test equipment (ATE). Test structures may be needed to test for speed-related defects in stacked dies 106.

Many different kinds of electronic devices may benefit from testing. Different kinds of such devices include, but are not limited to, cellular telephones, wireless modems, computers, digital music players, Global Positioning System units, Personal Digital Assistants, gaming devices, etc. One group of devices includes those that may be used with wireless communication systems. As used herein, the term “wireless communication device” refers to an electronic device that may be used for voice and/or data communication over a wireless communication network. Examples of wireless communication devices include cellular phones, handheld wireless devices, wireless modems, laptop computers, personal computers, etc. A wireless communication device may alternatively be referred to as an access terminal, a mobile terminal, a subscriber station, a remote station, a user terminal, a terminal, a subscriber unit, user equipment, a mobile station, etc.

A wireless communication network may provide communication for a number of wireless communication devices, each of which may be serviced by a base station. A base station may alternatively be referred to as an access point, a Node B, or some other terminology. Base stations and wireless communication devices may make use of integrated circuits. However, many different kinds of electronic devices, in addition to the wireless devices mentioned, may make use of integrated circuits.

Microprocessing devices often need access to external memory to store data and program instructions. In some devices, the memory device is external to the package 102 and communicates with a microprocessor through an external interface. As memory requirements continue to increase, additional memory devices are often required to meet speed and bandwidth requirements. However, interfacing to external memory devices may require more pins on the package 102, as well as additional space within the electronic device that uses the microprocessor and memory devices. The additional memory may thus result in a relatively significant increase in cost. One cost-efficient alternative is to stack additional memory devices inside the package 102 with the microprocessor.

A microprocessor and memory devices are typically configured on a silicon wafer referred to as a die 106. Multiple dies 106 may be stacked within a single package 102 and sold as an integrated circuit. Pins are located outside the package 102 to allow the devices in the package 102 to be electronically coupled with other devices. While some of the pins may be allocated for external interfaces to test the dies 106 in the package 102, it is typically desirable to allocate as many of the pins as possible to other types of signals, such as control, data, power and ground signals.

As integrated circuit technology scales down, the supply voltage must be reduced to prevent breakdown of gate insulators in electronic components. Reducing the supply voltage has the added benefit of reducing the dynamic power consumption in an integrated circuit. However, voltage reduction may also result in a linear increase in the propagation delay of logic gates within the integrated circuit. Therefore, the threshold voltage of the transistors must be lowered to maintain the circuit speed. This reduction in threshold voltage may result in a significant increase in leakage current. Leakage current occurs when defects manifest themselves as a short that may affect functionality and/or increase the static power consumption in a circuit.

Each die 106 in a stack may be tested comprehensively before packaging at the wafer level 118. The dies 106 can be damaged during assembly. Thus, additional testing may be performed at the package level once the dies 106 have been packaged together. Most failures are due to mechanical stress and/or electrostatic discharge, which can cause additional leakage current at one or more of the pins. Leakage current can drain power supplies in battery-powered devices more rapidly than anticipated. It is therefore desirable to test packaged devices under expected operating conditions at the package level to ensure the devices are performing within allowable parameters.

Most suppliers of integrated circuit devices stack memory dies 106 to eliminate the external memory devices altogether. Such configurations may leave the external interface pins unused. Accordingly, the unused pins can be tied to the stacked memory interface, allowing full access to the stacked device at package 102 level for comprehensive testing.

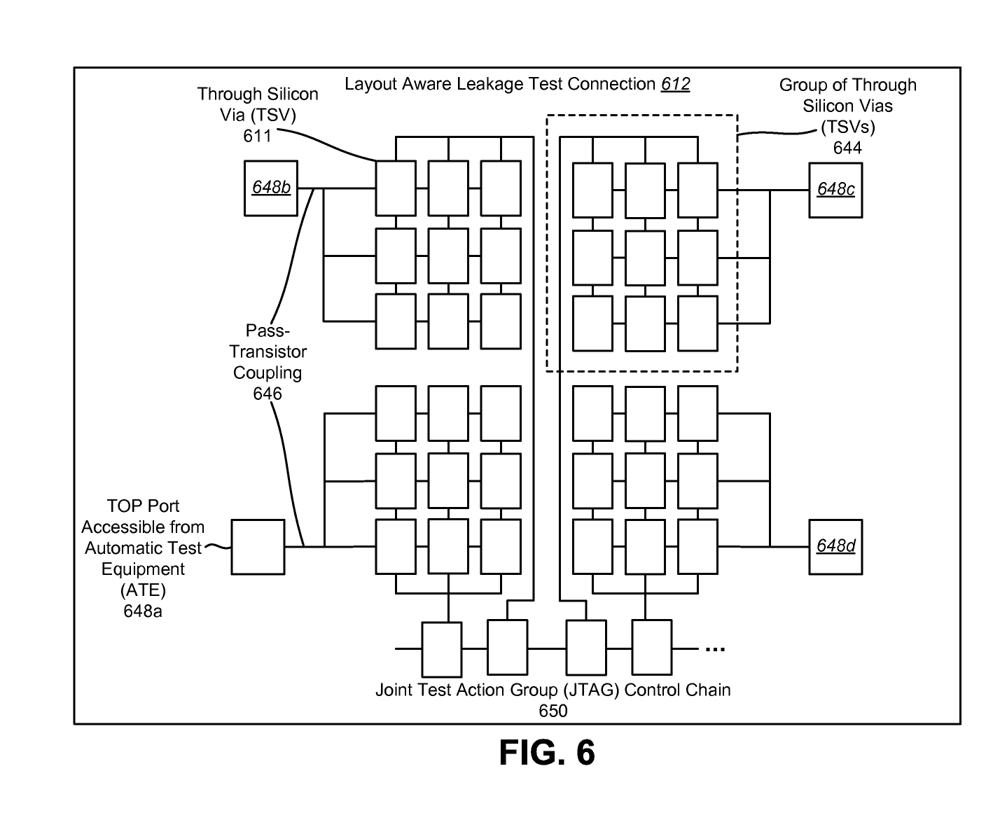

In some configurations, an external memory system may be supplemented with a stacked memory die 106. As a result, there may be no spare pins available on the package to access the memory signals of the stacked die 106. Since there are no dedicated pins, some pins on the package 102 may be shared between the stacked die signals. When stacking dies 106 in a package 102, Through Silicon Vias (TSVs) 111a-b may be used to connect the dies 106. Because there are a large number of Through Silicon Via (TSV) signals, any routing overhead incurred by a leakage test at the wafer level 118 and at the package 102 level should be minimized. During multi-site leakage testing, only a limited set of pins are accessible from the testing equipment 104. However, there may be a large number of Through Silicon Vias (TSVs) 111. A layout aware leakage test connection 112a-c on each die 106 may be used to perform leakage tests. Layout aware leakage test connections 112 are discussed in additional detail below in relation to FIG. 6.

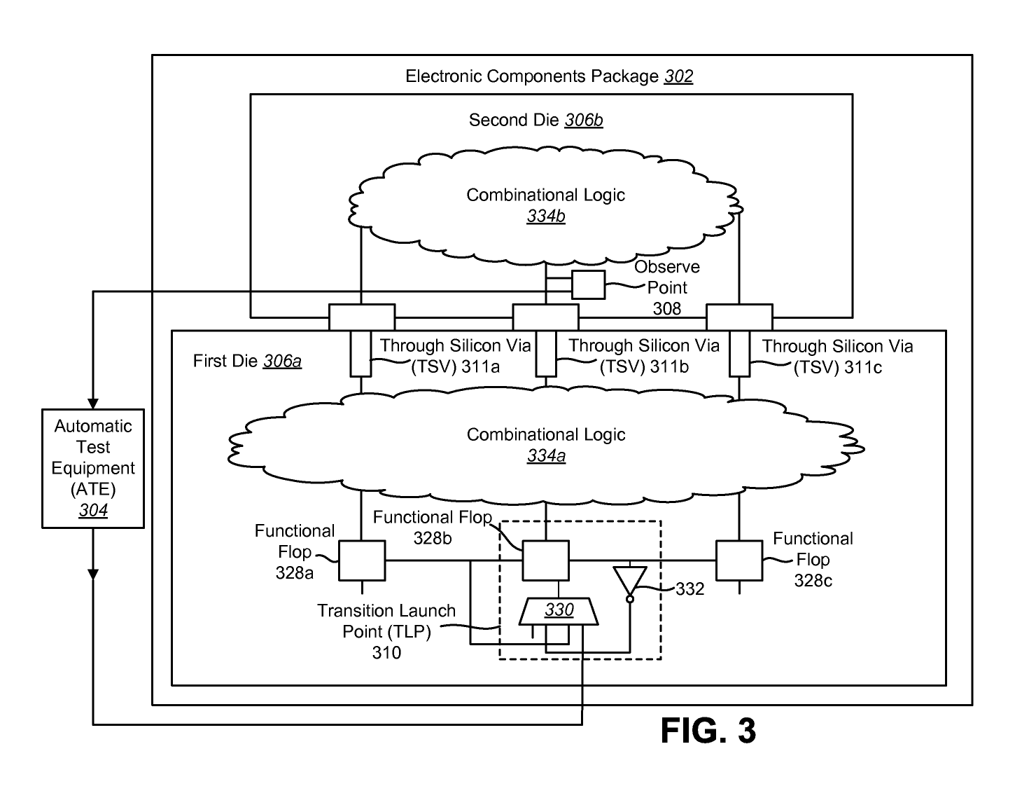

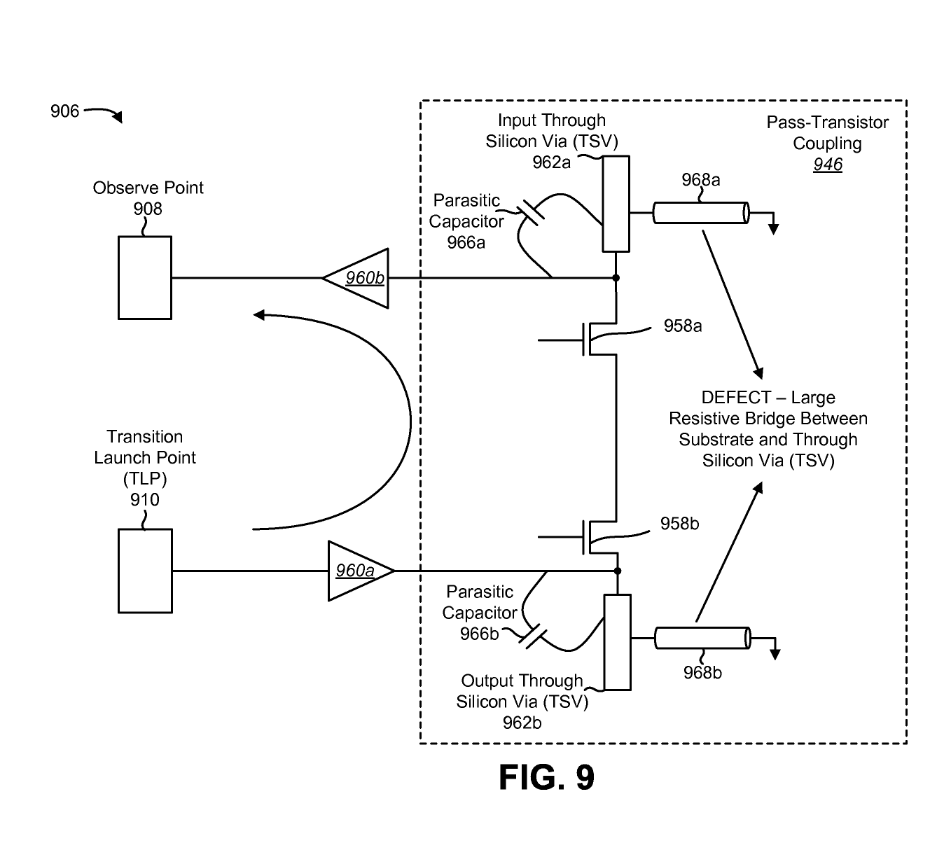

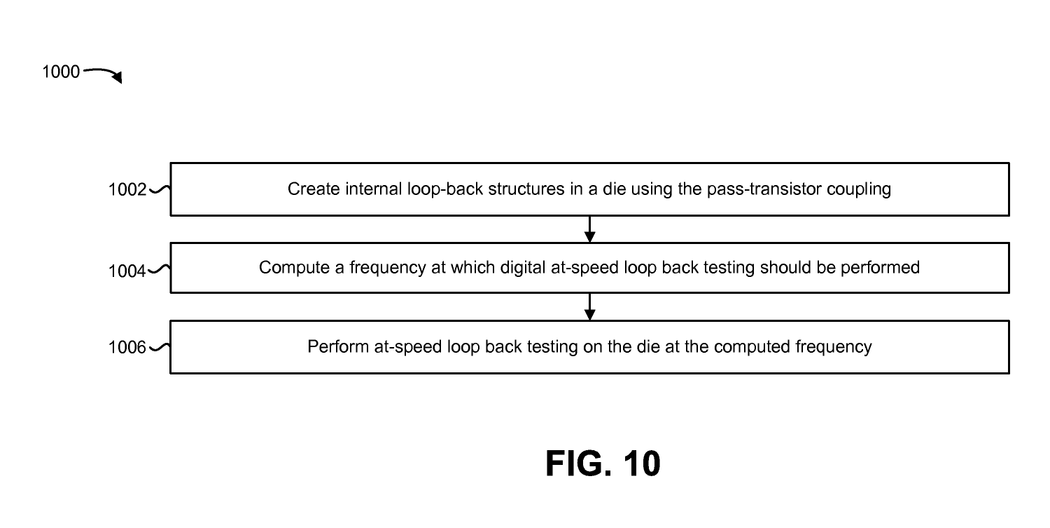

Each die 106 may include Transition Launch Points (TLPs) 110a-c to allow at-speed testing. At-speed data may be launched from one die 106 through a Transition Launch Point (TLP) 110, passed to another die 106 using one or more Through Silicon Vias (TSVs) 111 and captured using observe points 108a-c. A Transition Launch Point (TLP) 110 may be capable of generating at-speed raising/falling transitions to test any speed-related defect in the Through Silicon Via (TSV) 111 path. Transition Launch Points (TLPs) 110 are discussed in additional detail below in relation to FIG. 3. A Transition Launch Point (TLP) 110 does not impact the timing of the functional path-under-test. A Transition Launch Point (TLP) 110 may also behave as a scan flop during the automatic test pattern generation (ATPG) mode. A Transition Launch Point (TLP) 110 may also be used to test speed-related defects at the wafer level 118. Testing for speed-related defects at the wafer level 118 is discussed in additional detail below in relation to FIG. 9 and FIG. 10.

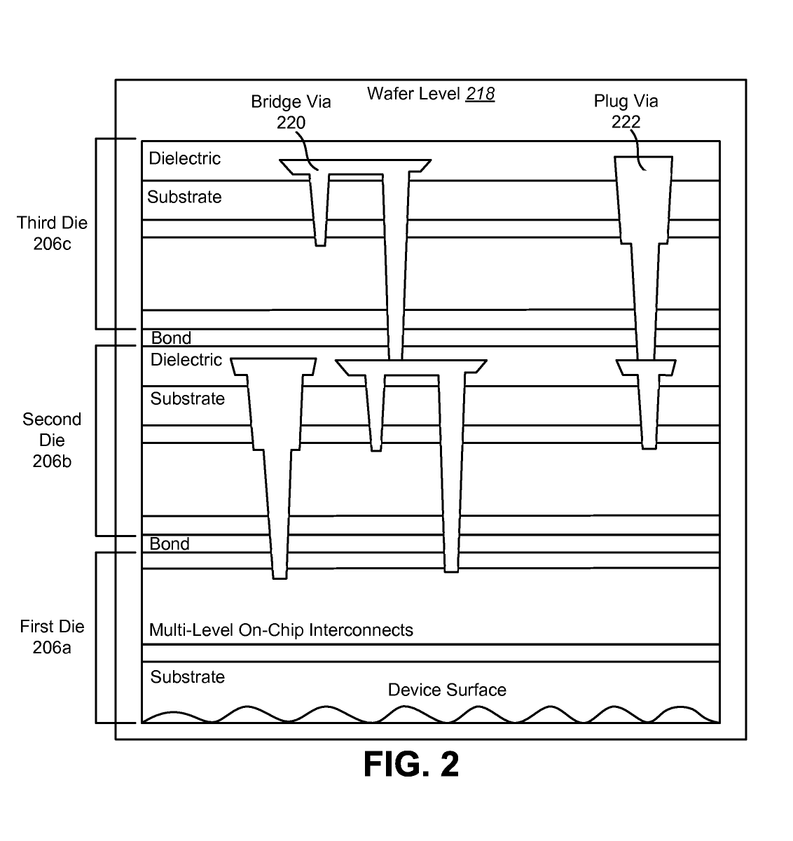

FIG. 2 illustrates stacked dies 206a-c at the wafer level 218. The stacked dies 206 may include a first stacked die 206a, a second stacked die 206b and a third stacked die 206c. In a stacked die 206, dies 206 may be stacked vertically using vias through silicon (referred to herein as Through Silicon Vias (TSVs) 111) to make connections. Examples of Through Silicon Vias (TSVs) 111 include a bridge via 220 and a plug via 222. One benefit of a stacked die 206 is new architectural and partitioning capabilities. A stacked die 206 may have extreme chip-to-chip bandwidth. A stacked die 206 may also overcome processor speed/memory access gap. Furthermore, a stacked die 206 may have a new cache architecture for multi-core designs.

Stacked dies 206 have a higher package density, allowing for very thin dies 206 stacked on top of each other, removing the need for wire bond. Interconnections down to 2-6 microns may allow tighter package designs and a smaller package body size. Furthermore, the shorter electrical paths in stacked dies 206 may lead to improved performance. Finally, stacked dies 206 may have improved time-to-market (TTM) and reuse compared to a System on a Chip (SoC). To stack multiple dies 206, through silicon stacking (TSS) may be used. However, through silicon stacking (TSS) may result in speed-related defects due to the capacitive coupling/cross-talks. Through silicon stacking (TSS) may also result in resistive shorts manifested as stuck-at type defects. Through silicon stacking (TSS) also has the potential for increased leakage current due to shorts affecting power consumption. To detect these defects, both wafer level 218 and package 102 level testing may be performed.

FIG. 3 is a block diagram illustrating an electronic components package 302 that is configured for at-speed testing. The electronic components package 302 of FIG. 3 may be one configuration of the electronic components package 102 of FIG. 1. The electronic components package 302 may be coupled to automatic test equipment (ATE) 304. The automatic test equipment (ATE) 304 may perform at-speed testing on the dies 306a-b within the electronic components package 302.

The electronic components package 302 may include a first die 306a and a second die 306b. In one configuration, the electronic components package 302 may include additional die 306 that are not shown. The first die 306a may be coupled to the second die 306b using one or more Through Silicon Vias (TSVs) 311a-c.

The first die 306a may include one or more functional flops 328a-c. A functional flop 328a-c may be a D-flip flop. The functional flops 328 may be coupled to combinational logic 334a within the first die 306a. Some of the functional flops 328b may be converted into Transition Launch Points (TLPs) 310. Although only one functional flop 328b is shown as converted into a Transition Launch Point (TLP) 310, multiple functional flops 328 may be converted into Transition Launch Points (TLPs) 310 as needed. A Transition Launch Point (TLP) 310 may include a 4:1 multiplexer 330. The output of the 4:1 multiplexer 330 may be coupled to the input of the functional flop 328b. The inputs to the 4:1 multiplexer 330 may include an input from the automatic test equipment (ATE) 304, two inputs from a preceding functional flop 328a and an inverted input (using an inverter 332 in the Transition Launch Point (TLP) 310) from a subsequent functional flop 328c.

A Transition Launch Point (TLP) 310 may operate in four different modes (m₁m₀=00, 01, 10, 11). The Transition Launch Point (TLP) 310 may be programmed to each of the different modes by a test engineer. The 00 mode may be referred to as Capture Mode. In capture mode, the Transition Launch Point (TLP) 310 may capture data during the functional mode as well as core-automatic test pattern generation (ATPG) mode (i.e., when the core logic is in the automatic test pattern generation (ATPG) mode). The 01 mode may be referred to as Shift Mode. The Transition Launch Points (TLPs) 310 may be daisy-chained to form one or more scan chains. Data can then be shifted in/out of a Transition Launch Point (TLP) 310 when the Transition Launch Point (TLP) 310 is in Shift Mode.

The 10 mode may be referred to as Through Silicon Via (TSV) 311 Launch Transition Mode. During Through Silicon Via (TSV) 311 at-speed testing of the first die 306a, the data stored in the Transition Launch Point (TLP) 310 may be inverted, launching a transition. This is accomplished using the inverter 332. The 11 mode may be referred to as the Through Silicon Via (TSV) 311 Launch Preceding Bit Mode. During Through Silicon Via (TSV) 311 at-speed testing, the Transition Launch Point (TLP) 310 may launch the data stored in the preceding scan bit. The 10 mode and the 11 mode provide improved controllability for the launch pattern of Through Silicon Via (TSV) 311 vectors. During the Through Silicon Via (TSV) 311 at-speed test capture phase, the m₀ bit may be left unconstrained so that the automatic test pattern generation (ATPG) can decide what mode gives better coverage. The 10 mode and the 11 mode also help improve coverage and generate robust vectors.

The 4:1 multiplexer 330 is added at the input side of the functional flop 328b to provide minimal impact to the Through Silicon Via (TSV) 311 path-under-test. Only those functional flops 328 that lead to an output-type Through Silicon Via (TSV) 311 are converted to Transition Launch Points (TLPs) 310. Functional flops 328 that capture data from an input-type Through Silicon Via (TSV) 311 may instead be converted to scan-flops. A Through Silicon Via (TSV) 311 may be either an input-type that provides input to the stacked die 306 or an output-type that acts as a port from the stacked die 306.

The second die 306b may include an observe point 308 that is located between a Through Silicon Via (TSV) 311b and the combinational logic 334b of the second die 306b. The observe point 308 may be coupled to the automatic test equipment (ATE) 304. The automatic test equipment (ATE) 304 may also be coupled to one of the inputs of the 4:1 multiplexer 330. In this way, the automatic test equipment (ATE) 304 may send at-speed testing vectors through the first die 306a and capture the response using one or more observe points 308 on the second die 306b.

A Transition Launch Point (TLP) 310 may be capable of generating at-speed rising/falling transitions to test for speed-related defects in the Through Silicon Via (TSV) 311 path. However, a Transition Launch Point (TLP) 310 does not impact the timing of the functional path-under-test. This is important because the functional path-under-test paths may be functionally timing critical. Because the Transition Launch Point (TLP) 310 does not impact the timing of the functional path-under-test, at-speed test quality is guaranteed because the real functional paths are tested. A Transition Launch Point (TLP) 310 may behave as a scan flop during the automatic test pattern generation (ATPG) mode. By providing additional controllability and observability, the Transition Launch Point (TLP) 310 may improve coverage during regular static-testing.

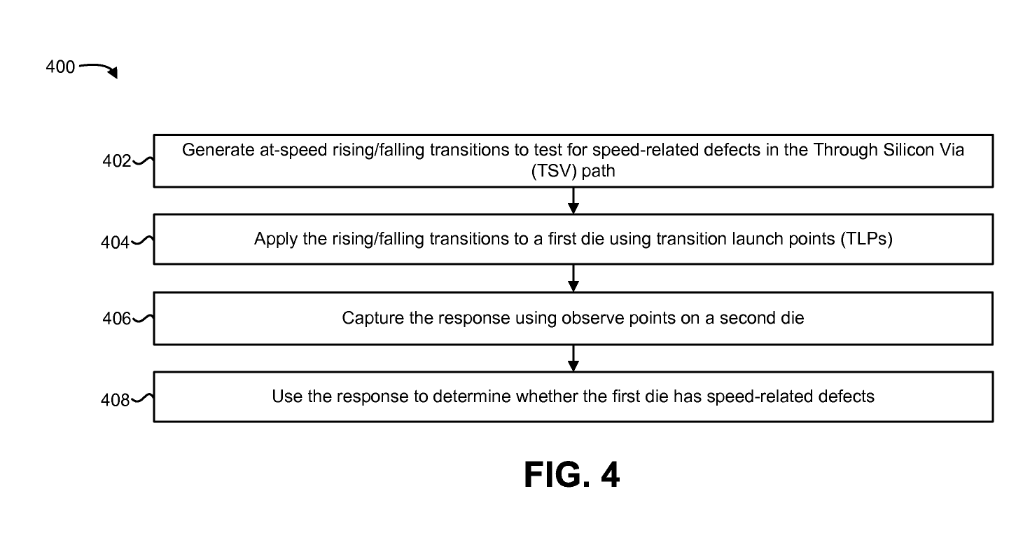

FIG. 4 is a flow diagram of a method 400 for at-speed testing of stacked die 306. The method 400 may be performed by automatic test equipment (ATE) 304. The automatic test equipment (ATE) 304 may generate 402 at-speed rising/falling transitions to test for speed-related defects in the Through Silicon Via (TSV) 311 path of the stacked die 306. The automatic test equipment (ATE) 304 may apply 404 the rising/falling transitions to a first die 306a using Transition Launch Points (TLPs) 310. The automatic test equipment (ATE) 304 may then capture 406 the response using observe points 308 on a second die 306b. Finally, the automatic test equipment (ATE) 304 may use 408 the response to determine whether the first die 306a has speed-related defects.

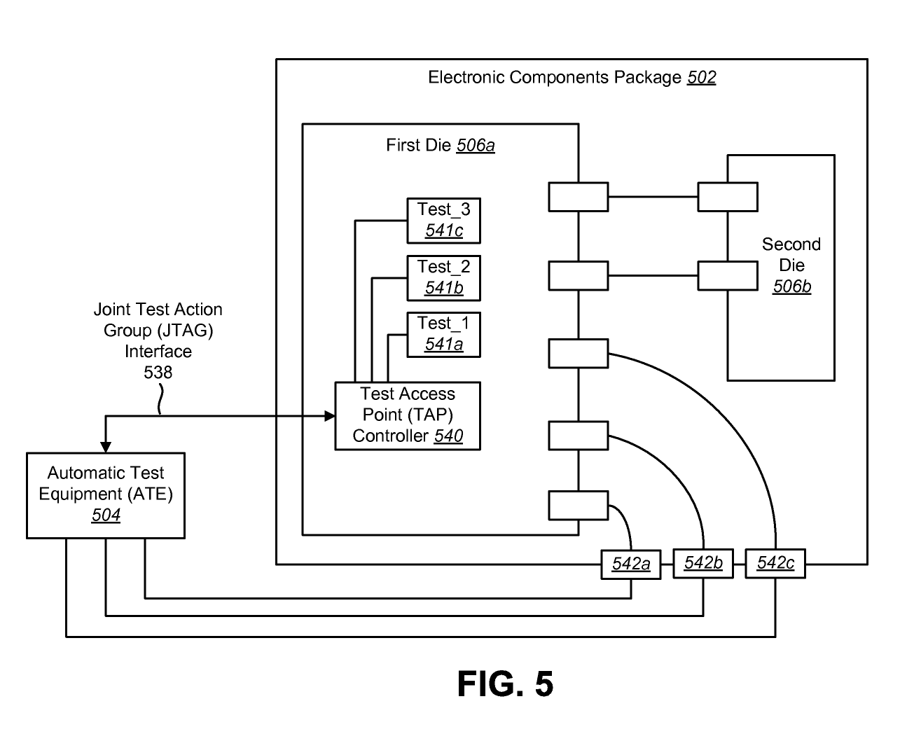

FIG. 5 is a block diagram illustrating testing using a Joint Test Action Group (JTAG) Test Access Port (TAP) controller 540. The Joint Test Action Group (JTAG) Specification, known as Institute of Electronic and Electrical Engineers (IEEE) 1149.1, requires Joint Test Action Group (JTAG) compliant devices to include specified types of pins, such as Test Clock, Test Data In, Test Data Out, Test Mode Select and an optional Test Reset Input. The Test Access Port (TAP) controller 540 may provide access to the test support functions built into the Joint Test Action Group (JTAG) compliant electronic components package 502.

A single cell of a shift-register (not shown) may be designed into the logic of the electronic components package 502 and linked to every digital pin of the electronic components package 502. The single cell may link the Joint Test Action Group (JTAG) circuitry to the internal core logic of the electronic components package 502, which can include microprocessors, microcontrollers, programmable logic devices, field programmable gate arrays (FPGAs), application-specific integrated circuits (ASICs), memory devices and any other devices that conform to the Joint Test Action Group (JTAG) specification. In one configuration, the electronic components package 502 may include double data rate (DDR) memory.

The electronic components package 502, the first die 506a and the second die 506b may be configured to be Joint Test Action Group (JTAG) compliant devices, with TEST_1 541a, TEST_2 541b and TEST_3 541c signals controlled via automatic test equipment (ATE) 504 interfaced with the Test Access Port (TAP) controller 540 using a Joint Test Action Group (JTAG) interface 538. Test and direction signals may be input at package bonding pads 542a-c. The test and direction signals may also be controlled via the automatic test equipment (ATE) 504. Thus, the automatic test equipment (ATE) 504 may perform at-speed testing, leakage testing and at-speed loopback testing on the first die 506a and the second die 506b.

FIG. 6 is a block diagram illustrating a layout aware leakage test connection 612. The layout aware leakage test connection 612 of FIG. 6 may be one configuration of the layout aware leakage test connection 112 of FIG. 1. The layout aware leakage test connection 612 may allow leakage testing of a die 106 at the wafer level 118 and package 102 level. Because there are a large number of Through Silicon Via (TSV) 611 signals, any routing overhead incurred by leakage tests should be minimized.

A leakage test is used to detect defects that manifest themselves as a short that may affect the functionality of an integrated circuit and/or the functional mode power consumption of the integrated circuit. When dies 106 are stacked, a leakage test may become more difficult because only a limited set of pins are accessible by the automatic test equipment (ATE) 504. Furthermore, there are a large number of Through Silicon Vias (TSVs) 611 in a stacked die 106. If the routing overhead is not minimized, multi-site leakage testing may become cost prohibitive.

Based on the layout aware leakage test connection 612, one or more groups 644 of Through Silicon Vias (TSVs) 611 may be formed. A group 644 of Through Silicon Vias (TSVs) 611 may include two or more Through Silicon Vias (TSVs) 611 that are physically close to each other. Two or more Through Silicon Vias (TSVs) 611 may be defined as physically close to each other if the distance between each Through Silicon Via (TSV) 611 on the x,y axis is less than a threshold T. The threshold T may be computed using different criteria (e.g., how many Through Silicon Vias (TSVs) 611 should be in each group).

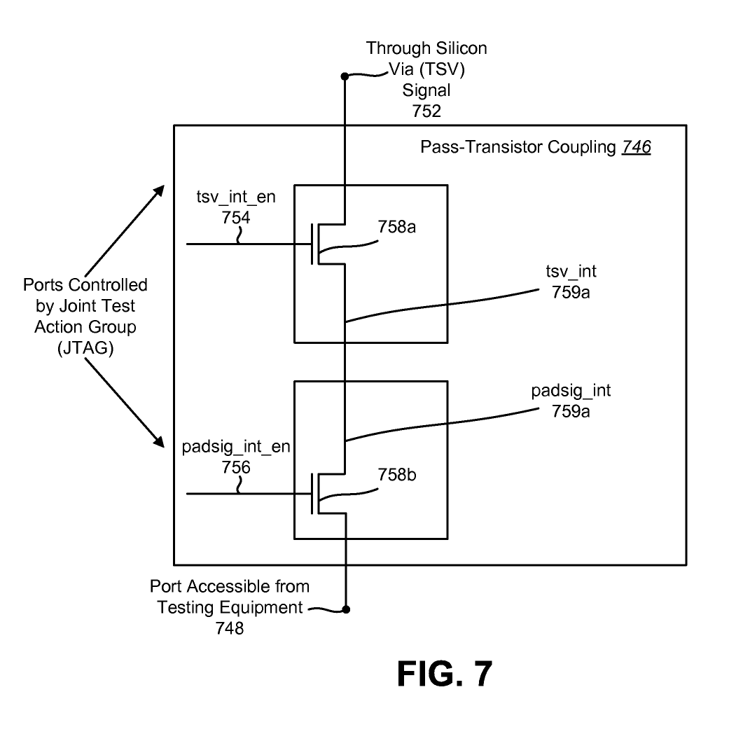

The size of each group 644 of Through Silicon Vias (TSVs) 611 may be based on the available Joint Test Action Group (JTAG) control bits and/or the number of top-level pins accessible from the automatic test equipment (ATE) 504. Each group 644 of Through Silicon Vias (TSVs) 611 may be coupled to an external pin 648a-d (a TOP port) that is accessible from the automatic test equipment (ATE) 504. The coupling may be a pass-transistor coupling 646. A pass-transistor coupling 646 is discussed in additional detail below in relation to FIG. 7. The Through Silicon Vias (TSVs) 611 may also be coupled to a Joint Test Action Group (JTAG) control chain 650. The Joint Test Action Group (JTAG) control chain 650 may be programmed to a certain value that determines how many of the Through Silicon Vias (TSVs) 611 are to be grouped together to measure the leakage during testing. In other words, the Joint Test Action Group (JTAG) control chain 650 allows the user to control how the leakage test should be conducted (i.e., how many Through Silicon Vias (TSVs) 611 should be grouped together for a leakage current measurement test). The Joint Test Action Group (JTAG) control chain 650 may be programmed to any value that may be required during the functional mode or the test mode for the correct operation. Herein, the Joint Test Action Group (JTAG) control chain 640 is used for the leakage test.

FIG. 7 is a circuit diagram illustrating a pass-transistor coupling 746. The pass-transistor coupling 746 of FIG. 7 may be one configuration of the pass-transistor coupling 646 of FIG. 6. The pass transistor coupling 746 may include a first transistor 758a and a second transistor 758b. The gate of the first transistor 758a may be a port controlled by the Joint Test Action Group (JTAG). The gate of the first transistor 758a may be coupled to a tsv_int_en signal 754. The first transistor 758a may also be coupled to the Through Silicon Via (TSV) 611 signal 752 (i.e., to a group 644 of Through Silicon Vias (TSVs) 611) and to the second transistor 758b. The gate of the second transistor 758b may also be a port controlled by the Joint Test Action Group (JTAG). The gate of the second transistor 758b may be coupled to a padsig_int_en signal 756. The second transistor 758b may also be coupled to a port 748 accessible from the automatic test equipment (ATE) 504. The tsv int signal 759a and the padsig int signal 759b are shown in between the first transistor 758a and the second transistor 758b.

The tsv_int_en signal 754 and the padsig int en signal 756 may be directly controlled by the Joint Test Action Group (JTAG) and hence can be programmed. When both the tsv_int_en signal 754 and the padsig int en signal 756 are asserted, the corresponding Through Silicon Via (TSV) 611 pin will be coupled with the padsig pin. This coupling essentially means that the Through Silicon Via (TSV) 611 pins can be driven through the padsig. The padsig can be driven from any external test equipment.

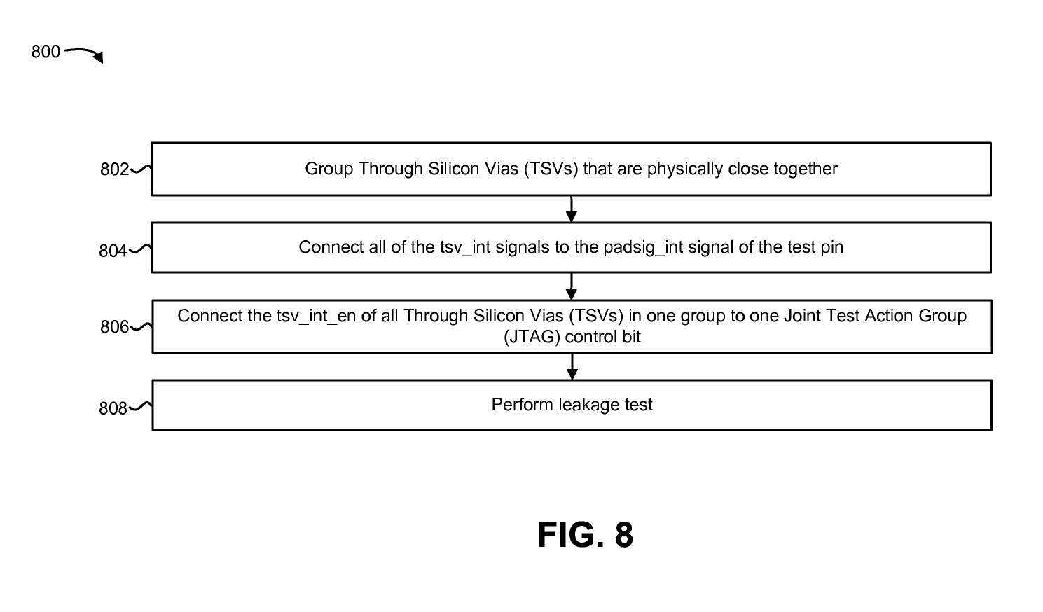

FIG. 8 is a flow diagram of a method 800 for performing a leakage test on a die 106. The leakage test may be performed at either the wafer level 118 (i.e., the die 106 is not yet stacked) or at the package 102 level (i.e., the die 106 is part of a stacked die 106). Through Silicon Vias (TSVs) 611 that are physically close together may be grouped 802 together. All of the tsv int signals may be connected 804 to the padsig int signal of the test pin. The tsv in en signal 754 of all the Through Silicon Vias (TSVs) 611 in one group 644 may be connected 806 to one Joint Test Action Group (JTAG) control bit of a Joint Test Action Group (JTAG) control chain 650. A leakage test may then be performed 808.

FIG. 9 is a circuit diagram illustrating a configuration for digital at-speed loop back testing of a die 906. Digital at-speed loop back testing may be used to test speed-related defects at the wafer level 118 of a die 906. Thus, the die 906 may not yet be part of a stacked die 106. The die 906 may include a Transition Launch Point (TLP) 910 and an observe point 908. The die 906 may also include a layout aware leakage test connection 612 that includes a pass-transistor coupling 946. In at-speed loop back testing, the pass-transistor coupling 946 may be reused to create internal loop-back structures. This way, at-speed loop back testing may be performed with no additional hardware cost.

The Transition Launch Point (TLP) 910 may be coupled to a first buffer 960a. The first buffer 960a may be coupled to a pass-transistor coupling 946. The pass-transistor coupling 946 may include a first transistor 958a and a second transistor 958b that are coupled to each other. The first buffer 960a may be coupled between the second transistor 958b and an output Through Silicon Via (TSV) 962b. The first transistor 958a may be coupled to an input Through Silicon Via (TSV) 962a. The first transistor 958a may also be coupled to a second buffer 960b. The second buffer 960b may then be coupled to an observe point 908.

A parasitic capacitor 966a may occur between the first transistor 958a and the input Through Silicon Via (TSV) 962a. A parasitic capacitor 966b may also occur between the second transistor 958b and the output Through Silicon Via (TSV) 962b. Furthermore, a defect such as a large resistive bridge between the substrate and the Through Silicon Via (TSV) 111 may occur. Since the loop back paths are not functional paths, they may have to be characterized using software tools to compute the frequency at which the at-speed loop back testing should be conducted. The Joint Test Action Group (JTAG) tsv int en bits should be enabled to turn on a minimal number of pass transistors while achieving 100% test coverage. The digital at-speed loop back testing may allow testing for defects such as large resistive bridges 968a-b between the substrate and a Through Silicon Via (TSV) 111. Many other speed-related defects that are not modeled may also be detected by the at-speed test besides the parasitic capacitors 962 and the large resistive bridges 968.

FIG. 10 is a flow diagram of a method 1000 for conducting digital at-speed loop back testing. The digital at-speed loop back testing may be performed at the wafer level 118. Internal loop-back structures in a die 906 may be created 1002 using a pass-transistor coupling 946. A frequency at which digital at-speed loop back testing should be performed may be computed 1004. This frequency may be computed by the creator/designer of the die 106. At-speed loop back testing at the computed frequency may then be performed 1006. The at-speed loop back testing may be performed 1006 using testing equipment 104. In one configuration, the testing equipment 104 may be automatic test equipment (ATE) 504.

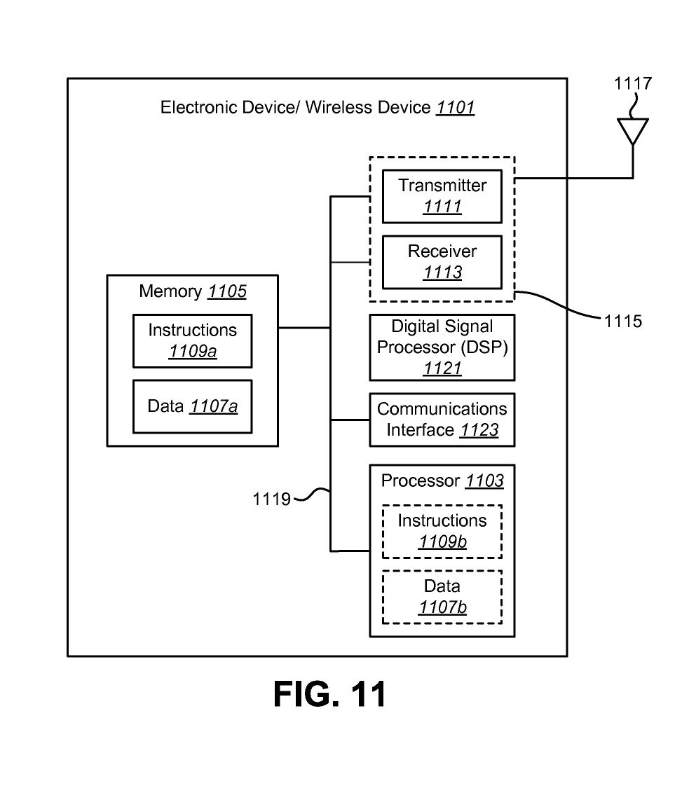

FIG. 11 illustrates certain components that may be included within an electronic device/wireless device 1101. The electronic device/wireless device 1101 may be an access terminal, a mobile station, a wireless communication device, a base station, a Node B, a handheld electronic device, etc. The electronic device/wireless device 1101 includes a processor 1103. The processor 1103 may be a general purpose single- or multi-chip microprocessor (e.g., an ARM), a special purpose microprocessor (e.g., a digital signal processor (DSP)), a microcontroller, a programmable gate array, etc. The processor 1103 may be referred to as a central processing unit (CPU). Although just a single processor 1103 is shown in the electronic device/wireless device 1101 of FIG. 11, in an alternative configuration, a combination of processors (e.g., an ARM and DSP) could be used.

The electronic device/wireless device 1101 also includes memory 1105. The memory 1105 may be any electronic component capable of storing electronic information. The memory 1105 may be embodied as random access memory (RAM), read-only memory (ROM), magnetic disk storage media, optical storage media, flash memory devices in RAM, on-board memory included with the processor, EPROM memory, EEPROM memory, registers, and so forth, including combinations thereof.

Data 1107a and instructions 1109a may be stored in the memory 1105. The instructions 1109a may be executable by the processor 1103 to implement the methods disclosed herein. Executing the instructions 1109a may involve the use of the data 1107a that is stored in the memory 1105. When the processor 1103 executes the instructions 1109a, various portions of the instructions 1109b may be loaded onto the processor 1103, and various pieces of data 1107b may be loaded onto the processor 1103.

The electronic device/wireless device 1101 may also include a transmitter 1111 and a receiver 1113 to allow transmission and reception of signals to and from the electronic device/wireless device 1101. The transmitter 1111 and receiver 1113 may be collectively referred to as a transceiver 1115. An antenna 1117 may be electrically coupled to the transceiver 1115. The electronic device/wireless device 1101 may also include (not shown) multiple transmitters, multiple receivers, multiple transceivers and/or multiple antennas.

The electronic device/wireless device 1101 may include a digital signal processor (DSP) 1121. The electronic device/wireless device 1101 may also include a communications interface 1123. The communications interface 1123 may allow a user to interact with the electronic device/wireless device 1101.

The various components of the electronic device/wireless device 1101 may be coupled together by one or more buses, which may include a power bus, a control signal bus, a status signal bus, a data bus, etc. For the sake of clarity, the various buses are illustrated in FIG. 11 as a bus system 1119.

The techniques described herein may be used for various communication systems, including communication systems that are based on an orthogonal multiplexing scheme. Examples of such communication systems include Orthogonal Frequency Division Multiple Access (OFDMA) systems, Single-Carrier Frequency Division Multiple Access (SC-FDMA) systems, and so forth. An OFDMA system utilizes orthogonal frequency division multiplexing (OFDM), which is a modulation technique that partitions the overall system bandwidth into multiple orthogonal sub-carriers. These sub-carriers may also be called tones, bins, etc. With OFDM, each sub-carrier may be independently modulated with data. An SC-FDMA system may utilize interleaved FDMA (IFDMA) to transmit on sub-carriers that are distributed across the system bandwidth, localized FDMA (LFDMA) to transmit on a block of adjacent sub-carriers, or enhanced FDMA (EFDMA) to transmit on multiple blocks of adjacent sub-carriers. In general, modulation symbols are sent in the frequency domain with OFDM and in the time domain with SC-FDMA.

The term “determining” encompasses a wide variety of actions and, therefore, “determining” can include calculating, computing, processing, deriving, investigating, looking up (e.g., looking up in a table, a database or another data structure), ascertaining and the like. Also, “determining” can include receiving (e.g., receiving information), accessing (e.g., accessing data in a memory) and the like. Also, “determining” can include resolving, selecting, choosing, establishing and the like.

The phrase “based on” does not mean “based only on,” unless expressly specified otherwise. In other words, the phrase “based on” describes both “based only on” and “based at least on.”

The term “processor” should be interpreted broadly to encompass a general purpose processor, a central processing unit (CPU), a microprocessor, a digital signal processor (DSP), a controller, a microcontroller, a state machine, and so forth. Under some circumstances, a “processor” may refer to an application specific integrated circuit (ASIC), a programmable logic device (PLD), a field programmable gate array (FPGA), etc. The term “processor” may refer to a combination of processing devices, e.g., a combination of a DSP and a microprocessor, a plurality of microprocessors, one or more microprocessors in conjunction with a DSP core, or any other such configuration.

The term “memory” should be interpreted broadly to encompass any electronic component capable of storing electronic information. The term memory may refer to various types of processor-readable media such as random access memory (RAM), read-only memory (ROM), non-volatile random access memory (NVRAM), programmable read-only memory (PROM), erasable programmable read-only memory (EPROM), electrically erasable PROM (EEPROM), flash memory, magnetic or optical data storage, registers, etc. Memory is said to be in electronic communication with a processor if the processor can read information from and/or write information to the memory. Memory that is integral to a processor is in electronic communication with the processor.

The terms “instructions” and “code” should be interpreted broadly to include any type of computer-readable statement(s). For example, the terms “instructions” and “code” may refer to one or more programs, routines, sub-routines, functions, procedures, etc. “Instructions” and “code” may comprise a single computer-readable statement or many computer-readable statements.

The functions described herein may be implemented in software or firmware being executed by hardware. The functions may be stored as one or more instructions on a computer-readable medium. The terms “computer-readable medium” or “computer-program product” refers to any tangible storage medium that can be accessed by a computer or a processor. By way of example, and not limitation, a computer-readable medium may comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Disk and disc, as used herein, includes compact disc (CD), laser disc, optical disc, digital versatile disc (DVD), floppy disk and Blu-ray® disc where disks usually reproduce data magnetically, while discs reproduce data optically with lasers.

The methods disclosed herein comprise one or more steps or actions for achieving the described method. The method steps and/or actions may be interchanged with one another without departing from the scope of the claims. In other words, unless a specific order of steps or actions is required for proper operation of the method that is being described, the order and/or use of specific steps and/or actions may be modified without departing from the scope of the claims.

Further, it should be appreciated that modules and/or other appropriate means for performing the methods and techniques described herein, such as those illustrated by FIGS. 4, 8, and 10, can be downloaded and/or otherwise obtained by a device. For example, a device may be coupled to a server to facilitate the transfer of means for performing the methods described herein. Alternatively, various methods described herein can be provided via a storage means (e.g., random access memory (RAM), read-only memory (ROM), a physical storage medium such as a compact disc (CD) or floppy disk, etc.), such that a device may obtain the various methods upon coupling or providing the storage means to the device.

It is to be understood that the claims are not limited to the precise configuration and components illustrated above. Various modifications, changes and variations may be made in the arrangement, operation and details of the systems, methods, and apparatus described herein without departing from the scope of the claims.

What is claimed is:

1. An integrated circuit configured for at-speed testing, comprising:
a first die comprising a transition launch point;
a second die comprising a first observe point; and
a first through silicon via that couples the first die to the second die.

2. The integrated circuit of claim 1, wherein the second die is stacked directly on top of the first die.

3. The integrated circuit of claim 1, further comprising:
a third die comprising a second observe point, wherein the third die is stacked directly on top of the second die; and
a second through silicon via that couples the second die to the third die.

4. The integrated circuit of claim 3, wherein automatic test equipment applies test signals to the first die using the transition launch point, and wherein the automatic test equipment captures a testing response from the first observe point on the second die.

5. The integrated circuit of claim 1, wherein testing equipment is coupled to the transition launch point of the first die and the first observe point of the second die.

6. The integrated circuit of claim 1, wherein the transition launch point does not impact the timing of a functional path-under-test, and wherein the transition launch point behaves as a scan flop during an automatic test pattern generation mode.

7. The integrated circuit of claim 1, wherein the transition launch point comprises:
a functional flop;
a multiplexer coupled to an input of the functional flop; and
an inverter.

8. The integrated circuit of claim 7, wherein the functional flop leads to an output-type through silicon via coupling the first die to the second die.

9. The integrated circuit of claim 1, wherein automatic test equipment applies test signals to the first die using the transition launch point, and wherein the automatic test equipment captures a testing response from the first observe point on the second die.

10. The integrated circuit of claim 9, wherein the test signals comprise at-speed rising/falling transitions to test for speed-related defects in the first die.

11. The integrated circuit of claim 1, wherein the transition launch point operates in one of four modes: capture mode, shift mode, through silicon via launch transition mode and through silicon via launch preceding bit mode.

12. The integrated circuit of claim 11, wherein the transition launch point captures data when the transition launch point is in capture mode.

13. The integrated circuit of claim 11, wherein when the transition launch point is in shift mode, multiple transition launch points are daisy chained to form a scan chain, and wherein data is shifted in/out of the transition launch point.

14. The integrated circuit of claim 11, wherein the transition launch point is operating in through silicon via launch transition mode, and wherein data stored in the transition launch point is inverted using an inverter.

15. The integrated circuit of claim 11, wherein the transition launch point is operating in through silicon via launch preceding bit mode, and wherein the transition launch point launches data stored in a preceding scan bit.

16. A method for at-speed testing of an integrated circuit, comprising:
generating transitions to test for speed-related defects in a through silicon via path of the integrated circuit;
applying the transitions to a first die in the integrated circuit using a transition launch point;
capturing a response from the integrated circuit using a first observe point on a second die; and
using the response to determine whether the first die has speed-related defects.

17. The method of claim 16, wherein the integrated circuit comprises a first through silicon via that couples the first die to the second die.

18. The method of claim 16, wherein the second die is stacked directly on top of the first die.

19. The method of claim 16, wherein the integrated circuit comprises:
a third die comprising a second observe point, wherein the third die is stacked directly on top of the first die, and wherein the second die is stacked directly on top of the third die;
a first through silicon via that couples the first die to the third die; and
a second through silicon via that couples the second die to the third die.

20. The method of claim 19, wherein automatic test equipment applies test signals to the first die using the transition launch point, and wherein the automatic test equipment captures a testing response from the first observe point on the second die.

21. The method of claim 16, wherein testing equipment is coupled to the transition launch point of the first die and the first observe point of the second die.

22. The method of claim 16, wherein the transition launch point does not impact the timing of a functional path-under-test, and wherein the transition launch point behaves as a scan flop during an automatic test pattern generation mode.

23. The method of claim 16, wherein the transition launch point comprises:
a functional flop;
a multiplexer coupled to an input of the functional flop; and
an inverter.

24. The method of claim 23, wherein the functional flop leads to an output-type through silicon via coupling the first die to the second die.

25. The method of claim 16, wherein the method is performed by automatic test equipment.

26. The method of claim 16, wherein the transitions comprise at-speed rising/falling transitions.

27. The method of claim 16, wherein the transition launch point operates in one of four modes: capture mode, shift mode, through silicon via launch transition mode and through silicon via launch preceding bit mode.

28. The method of claim 27, wherein the transition launch point captures data when the transition launch point is in capture mode.

29. The method of claim 27, wherein when the transition launch point is in shift mode, multiple transition launch points are daisy chained to form a scan chain, and wherein data is shifted in/out of the transition launch point.

30. The method of claim 27, wherein the transition launch point is operating in through silicon via launch transition mode, and wherein data stored in the transition launch point is inverted using an inverter.

31. The method of claim 27, wherein the transition launch point is operating in through silicon via launch preceding bit mode, and wherein the transition launch point launches data stored in a preceding scan bit.

32. An integrated circuit configured for leakage testing, comprising:
a group of through silicon vias comprising a plurality of through silicon vias;
a pass-transistor coupling that couples the group of through silicon vias to testing equipment; and
a testing control chain.

33. The integrated circuit of claim 32, wherein the pass-transistor coupling couples the group of through silicon vias to a port that is accessible by the testing equipment.

34. The integrated circuit of claim 33, wherein the pass-transistor coupling comprises:
a first transistor coupled to the group of through silicon vias; and
a second transistor coupled between the first transistor and the port.

35. The integrated circuit of claim 34, wherein a gate of the first transistor is coupled to a Joint Test Action Group control bit, and wherein a gate of the second transistor is coupled to a test pin.

36. The integrated circuit of claim 32, wherein the size of the group of through silicon vias is based on available Joint Test Action Group control bits.

37. The integrated circuit of claim 32, wherein the size of the group of through silicon vias is based on the number of top level pins accessible from the testing equipment.

38. A method for digital at-speed loop back testing, comprising:
creating an internal loop-back structure in a die using a pass-transistor coupling;
computing a frequency at which digital at-speed loop back testing should be performed; and
performing at-speed loop back testing on the die at the frequency.

39. The method of claim 38, wherein the die comprises:
an observe point; and
a transition launch point, wherein the pass-transistor coupling is coupled between the transition launch point and the observe point.

40. The method of claim 39, wherein the pass-transistor coupling comprises:
a first transistor coupled to the observe point; and
a second transistor coupled between the first transistor and the transition launch point.

41. The method of claim 40, wherein a gate of the first transistor is coupled to a Joint Test Action Group control bit, and wherein a gate of the second transistor is coupled to a test pin.

42. The method of claim 40, wherein the first transistor is coupled to an input through silicon via, and wherein the second transistor is coupled to an output through silicon via.

43. The method of claim 39, wherein the transition launch point comprises:
a functional flop;
a multiplexer coupled to an input of the functional flop; and
an inverter.

44. An apparatus configured for at-speed testing of an integrated circuit, comprising:
means for generating transitions to test for speed-related defects in a through silicon via path of the integrated circuit;
means for applying the transitions to a first die in the integrated circuit using a transition launch point;
means for capturing a response from the integrated circuit using a first observe point on a second die; and
means for using the response to determine whether the first die has speed-related defects.

45. The apparatus of claim 44, wherein the transition launch point comprises:
a functional flop;
a multiplexer coupled to an input of the functional flop; and
an inverter.

46. The apparatus of claim 45, wherein the functional flop leads to an output-type through silicon via coupling the first die to the second die.

47. A computer-program product for at-speed testing of an integrated circuit, the computer-program product comprising a non-transitory computer-readable medium having instructions thereon, the instructions comprising:
code for causing an apparatus to generate transitions to test for speed-related defects in a through silicon via path of the integrated circuit;
code for causing the apparatus to apply the transitions to a first die in the integrated circuit using a transition launch point;
code for causing the apparatus to capture a response from the integrated circuit using a first observe point on a second die; and
code for causing the apparatus to use the response to determine whether the first die has speed-related defects.

48. The computer-program product of claim 47, wherein the transition launch point comprises:
a functional flop;
a multiplexer coupled to an input of the functional flop; and
an inverter.

49. The computer-program product of claim 48, wherein the functional flop leads to an output-type through silicon via coupling the first die to the second die.
